(19) United States
(12) Patent Application Publication
(10) Pub. No.: US 2005/0156322 A1
(43) Pub. Date: Jul. 21, 2005

(54) Thin semiconductor package including stacked dies

(76) Inventors: Lee John Smith, Chandler, AZ (US); David Albert Zoba, Chandler, AZ (US)

Correspondence Address: GUNNISON MCKAY & HODGSON, LLP;GARDEN WEST OFFICE PLAZA, SUITE 220, 1900 GARDEN ROAD, MONTEREY, CA, 93940, US

(21) Appl. No.: 09/944,732

(22) Filed: Aug. 31, 2001

(51) Int. Cl. H01L 23/02

(52) U.S. Cl. 257/778

(57) ABSTRACT

A semiconductor package is disclosed that includes multiple combinations of stacked or side by side semiconductor chips, at least one of which is at least partially disposed within a through hole formed in a substrate. Another embodiment includes a package with a metal core for improving mechanical strength, heat dissipation, electrical grounding, and power distribution characteristics of the packages. The substrate may be configured to facilitate stacking additional semiconductor packages.

### BACKGROUND

1. Field of the Invention

The present invention relates to semiconductor packaging and more particularly to methods and structures for mounting multiple die, or chips, into a thin package.

2. Description of the Related Art

A typical ball grid array (BGA) semiconductor package includes a semiconductor chip, also referred to as a “die,” mounted on an upper surface of an insulative, printed wiring substrate. The substrate may conventionally be made of a glass fiber filled organic laminate, such as FR4 board, FR5 board, or BT board. The substrate may include dielectric film-based laminate, such as polyimide, or ceramic based substrate, or other high density interconnect substrates, and typically has interconnected, conductive circuit patterns on upper and lower surfaces thereof. A hardened encapsulant material covers the chip, the upper surface of the substrate, and electrical conductors, such as wire ribbons, or bond wires, that extend between the chip and the circuit patterns on the upper surface of the substrate. Conductive balls or other input/output terminals are formed on the circuit patterns of the lower surface of the substrate.

Consistent with a trend toward smaller and thinner packages, a single semiconductor chip is sometimes mounted within a central through hole of the substrate. The chip is supported in the through hole by the hardened encapsulant material. Conventional packages, however, do not provide for more than a single chip to be mounted in such a package. Because conventional chip packages are limited to a single chip within a central substrate through hole, the functionality of these packages is limited to that of a single chip.

### SUMMARY OF THE INVENTION

A semiconductor package is provided, which includes a substrate having opposing first and second surfaces and a through hole extending through the substrate between the first and second surfaces. A first conductive circuit pattern is disposed on the first surface of the substrate and a second conductive circuit pattern is disposed on the second surface of the substrate. A first semiconductor chip having opposing active and inactive surfaces is at least partially disposed within the through hole, with the active surface of the first semiconductor chip being electrically connected to the first conductive circuit pattern. A second semiconductor chip also having opposing active and inactive surfaces is electrically connected to the second conductive circuit pattern. The second semiconductor chip may also be at least partially disposed within the through hole.

In another embodiment, the active surfaces of the first and second semiconductor chips are oriented in a same direction and are electrically coupled to a same conductive circuit pattern disposed on a single face of the substrate.

Pursuant to yet another embodiment, the substrate includes a metal core with a dielectric material disposed on first and second surfaces thereof. The inactive surfaces of the first and second semiconductor chips are mounted within recesses formed in the dielectric material on opposing sides of the metal core.

Another embodiment provides for the first and second semiconductor chips being disposed within the through hole formed in the substrate in a side by side relationship. In this embodiment, wire ribbons electrically connect active surfaces of the first and second semiconductor chips to each other and to the first surface of the substrate.

In addition, these semiconductor packages may be configured as stackable packages and stacked with other packages to form thin stacks of semiconductor packages.

Accordingly, the packages of the present invention permit multiple chips to be mounted in a thin semiconductor package. These and other aspects, features, and capabilities of the present invention will be clear from a reading of the following detailed description of the exemplary embodiments and the accompanying drawings.

### BRIEF DESCRIPTION OF THE DRAWINGS

FIG. 1 is a cross-sectional side view of a semiconductor package in accordance with an embodiment of the present invention.

FIG. 2 is a cross-sectional side view of a semiconductor package in accordance with an embodiment of the present invention.

FIG. 3 is a cross-sectional side view of a semiconductor package in accordance with an embodiment of the present invention.

FIG. 3A is a cross-sectional side view of a semiconductor package in accordance with an embodiment of the present invention.

FIG. 4 is a cross-sectional side view of a semiconductor package in accordance with an embodiment of the present invention.

FIG. 4A is a cross-sectional side view of a semiconductor package in accordance with an embodiment of the present invention.

FIG. 5 is a cross-sectional side view of a semiconductor package in accordance with an embodiment of the present invention.

FIG. 6 is a cross-sectional side view of a stack of semiconductor packages in accordance with an embodiment of the present invention.

FIG. 7 is a cross-sectional side view of a stack of semiconductor packages in accordance with an embodiment of the present invention.

FIG. 8 is a cross-sectional side view of a stack of semiconductor packages in accordance with an embodiment of the present invention.

FIG. 9 is a cross-sectional side view of a semiconductor package in accordance with an embodiment of the present invention.

In the various drawings of the exemplary embodiments, similar features of the various embodiments typically have the same reference numbers.

### DETAILED DESCRIPTION

The present application has relation to semiconductor packages and methods disclosed in U.S. patent application Ser. Nos. 09/566,069, 091574,541, 09/574,006, 09/812,426, and 09/774,952, all of which applications are incorporated herein by reference in their respective entireties. The present invention may be applied to some or all of the semiconductor packages disclosed in those applications. Further, the assembly methods disclosed in those applications may be modified in accordance with the present invention.

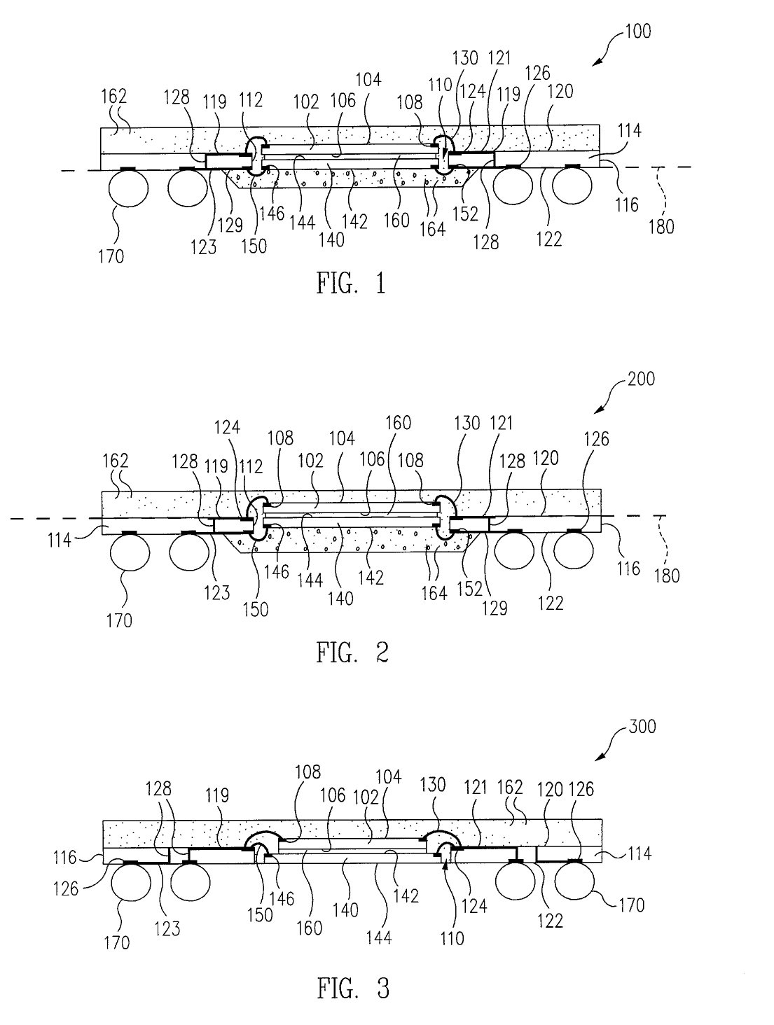

FIG. 1 shows a semiconductor package 100 in accordance with one embodiment of the present invention. Semiconductor package 100 includes a rectangular semiconductor chip 102 having an active surface 104 and an opposite inactive surface 106. The active surface 104 includes a plurality of input/output pads 108 located adjacent to the peripheral edges of active surface 104. Practitioners in the art will appreciate that polishing inactive second face 106 may thin the semiconductor chip 102.

As illustrated, the semiconductor chip 102 is at least partially disposed within a rectangular through hole 110 that extends vertically through a central portion of an interconnective substrate, denoted herein as substrate 114. Alternatively, the semiconductor chip 102 may be positioned over the through hole 110, or may be fully within the through hole 110.

The substrate 114 is rectangular and has an orthogonal inner wall 112 around and defining the through hole 110 and an orthogonal peripheral outer wall 116. The inner wall 112 and the outer wall 116 each have four corners. Each corner of inner wall 112 is generally aligned with a corresponding corner of outer wall 116. The substrate 114 may be composed of a resin layer and has an upward-facing first face 120 with a layer of electrically conductive circuit patterns 121 thereon, and an opposite downward-facing second face 122 with a layer of electrically conductive circuit patterns 123 disposed thereon.

As practitioners are well aware, the resin layer of substrate 114 may be formed from BT (bismaleimide triazine) board, FR4 board, FR5 board, or a some other rigid glass fiber filled organic (e.g., epoxy) laminate of the type used to make printed circuit board substrates for semiconductor packages. Alternatively, the resin layer of the substrate 114 may be formed of a flexible, insulative material, such as polyimide. An example thickness of the substrate 114 is 85 mm.

The circuit patterns 121 on the first face 120 of the substrate 114 each include bond fingers 124 proximate to the through hole 110 and traces 119. The traces 119 electrically connect the bond fingers 124 to vias 128. The vias 128 each electrically connect to a circuit pattern 123 on the second face 122 of the substrate 114. The circuit patterns 123 of the second face 122 each include traces 129 that extend from the vias 128 to a land 126, to which an interconnection structure, such as a solder ball 170 may be fused. The circuit patterns 123 also include a bond finger 152 adjacent the through hole 110, which is connected by the traces 129 either to a land 126 or a via 128.

The circuit patterns 121 and 123 may be formed of copper, other metals, conductive ink, or other conductive materials. Moreover, the bond fingers 124 may be plated with gold or silver, and the lands 126 may be plated with conductive metal such as, but not limited to gold, silver, nickel or palladium, or combinations thereof, to facilitate connections thereto. The lands 126 may also have an organic or inorganic coating to prevent oxidation of the lands 126.

The circuit patterns 121 and 123 on the first and second faces 120 and 122, respectively, of the substrate 114 may be covered with a hardened insulative cover coat. The cover coat may be formed from a polymer resin, such as an epoxy resin, to protect the circuit patterns from external physical, chemical, electrical, and mechanical shocks. The bond fingers 124 and the ball lands 126 are exposed for connections thereto through openings in the cover coat.

At least one terminal, such as input/output pad 108 of the semiconductor chip 102, is electrically connected to one of the bond fingers 124 by a conductive connection means, such as a wire bond or ribbon 130, which spans across the through hole 110 between the semiconductor chip 102 and the bond finger 124.

Another rectangular semiconductor chip 140 is shown as being disposed in the through hole 110 of the substrate 114. The semiconductor chip 140 is the same size as the semiconductor chip 102. For example, the semiconductor chips 102 and 140 may be the same type of memory chip.

Similar to the semiconductor chip 102, the semiconductor chip 140 has an active surface 142 and an opposite inactive surface 144. The active surface 142 includes a plurality of input/output pads 146 disposed about the peripheral edges of the active surface 142. Moreover, the active surface 142 is illustrated as being coplanar with the second face 122 of the substrate 114. Conductive connection means, such as a wire ribbons 150, span the through hole 110 and electrically connect the respective input/output pads 146 with corresponding bond fingers 152 disposed on the second face 122 of the substrate 114 adjacent the through hole 110. Inactive surface 144 may be polished to thin chip 140.

The inactive surfaces 106 and 144 of the chips 102 and 140, respectively, are attached to each other by an intervening die attach adhesive 160 to secure the chips 102 and 140 in rigid relation to each other. The die attach adhesive 160 may be selected from a wide variety of die attach adhesive materials, including epoxy and thermoplastic die attach adhesives, which may, or may not, be thermally or electrically conductive, depending on the particular requirements of the package.

Whether the semiconductor chip 102 is fully within, only partially within, or not in but over the through hole 110 is a function of, for instance, the thickness of the substrate 114, the thickness of the semiconductor chips 102 and 140 (one or both of which may be polished on their inactive surfaces to reduce their respective thicknesses), and the thickness of the die attach adhesive 160. Having the semiconductor chip 102 partially or fully within the through hole 110 with chip 140 achieves a thinner package for stacked semiconductor chips consistent with industry demands.

The semiconductor chip 102, the through hole 110, connection means 130, the die attach adhesive 160, at least a portion of the top surface 120 of the substrate 114, and at least the inactive surface 144 of the semiconductor chip 140, are within an insulative, protective encapsulant 162. The encapsulant 162 may be formed by molding and curing a resin material (e.g., epoxy), or by pouring and curing a liquid resin material (e.g., epoxy).

In the embodiment shown in FIG. 1, the encapsulant 162 covers the entire first face 120, although the entire first face 120 need not be encapsulated. That is, a perimeter of encapsulant 162 may be inward of the outer wall 116, leaving an uncovered peripheral portion of the first face 120. In addition, encapsulant 162 covers the peripheral sidewalls of the lower semiconductor chip 140, but does not cover the active surface 142 of the semiconductor chip 140 or the lower second face 122 of the substrate 114. The encapsulant 162 connects the chips 102 and 140 to the substrate 114 in addition to insulating and protecting the encapsulated structures.

A second encapsulant 164 is illustrated as encapsulating the active surface of the semiconductor chip 140, the wire ribbons 150, and at least a portion of the second face 122 of substrate 114. Advantageously, the encapsulant 164 is individually molded or poured, rather than gang molded or gang poured, so as to not encapsulate the entire second face 122 and thereby to permit a plurality of optional conductive balls 170 to be fused to the lands 126 disposed on the second face 122 beyond the perimeter of the second encapsulant 164. The second encapsulant 164 may comprise the same or a different type of encapsulation material as the encapsulant 162.

The optional conductive balls 170 (or other types of interconnects, such as conductive interconnect columns) may be made of lead/tin solder, lead free alloys, or some other conductive material, including conductive epoxy pastes and films, and are fused to the lands 126, and serve as input/output terminals for the semiconductor package 100. The conductive balls 170 are each electrically connected to a respective input/output pad 108 of semiconductor chip 102 and/or semiconductor chip 140 through respective circuit patterns 121 and/or circuit patterns 123, and a via 128 if applicable. The conductive balls 170 allow the semiconductor package 100 to be mounted on a motherboard (not shown) or to another semiconductor package (see, e.g., FIG. 6). Of course, the lands 126 themselves may serve as input/output terminals.

As shown, the active surfaces 104 and 142 of the chips 102 and 140, respectively, are oppositely oriented. That is, the active surfaces 104 and 142 face in opposite directions. Moreover, the active surfaces 104 and 142 are electrically coupled to bond fingers 124 or 152 on opposite first and second faces 120 and 122 of the substrate 114, respectively, thereby achieving a thin semiconductor package. In one embodiment, the total mounted height of the package 100 is less than about 0.85 mm.

In accordance with one embodiment, the semiconductor package 100 of FIG. 1 may be fabricated as follows. Initially, a substrate sheet, such as the substrate 114, is provided. Typically, a relatively large substrate sheet is used that includes rows and columns of interconnected substrates 114, each of which constitutes an identical package site. Each package site includes the circuit patterns 121 and 123, vias 128, and through hole 110 shown in FIG. 1. One package 100 is assembled at each package site of the substrate sheet, and then is singulated from the other packages 100 so assembled.

A layer of a cover material 180 is then temporarily applied to the second face 122 of the substrate 114, with the cover material 180 completely covering the opening of the through hole 110 at the second face 122. The cover material 180 may comprise plastic adhesive tape, e.g., a pressure sensitive or UV tape. The cover material 180 is advantageously easily removable and leaves little to no residue on the second face 122 after removal. One individual sheet of the cover material 180 may be applied over each through hole 110, or a large single sheet of the cover material 180 may be applied over the through holes 110 of multiple package sites of the substrate sheet.

With the cover material 180 in place, the semiconductor chip 140 is disposed in the through hole 110 with the active surface 142 in adhesive contact with the cover material 180. In this configuration, the cover material 180 maintains the semiconductor chip 140 within the through hole 110 so that the chip active surface 142 is substantially coplanar with the second face 122 of the substrate 114. The semiconductor chip 102 is mounted on the semiconductor chip 140 by disposing the die attach adhesive 160 between the facing inactive surfaces of 106 and 144 of the semiconductor chips 102 and 140, respectively, thereby securing the semiconductor chips 102 and 140 together in rigid relation to each other. The semiconductor chips 102 and 140 may be adhered to one another by the die attach adhesive 160 before or after the semiconductor chip 140 is positioned in the through hole 110 on cover material 180.

Next, the input/output pads 108 of the active surface 104 of the semiconductor chip 102 are each electrically connected to the conductive circuit pattern 121 disposed on the first face 120 of the substrate 114. In this example, the wire ribbons 130 are connected between the input/output pads 108 of the semiconductor chip 102 and the bond fingers 124 of the first face 120.

The semiconductor chips 102 and 140 are then encapsulated with encapsulant 162. The encapsulant 162 also fills the through hole 110 and secures the semiconductor chips 102 and 140 within the through hole 110. Encapsulant 162 contacts cover material 180 in the narrow space between the sides of the semiconductor chips 102, 140 and the inner wall 112 of the through hole 110. As mentioned above, this encapsulation may be by gang molding, as shown in FIG. 1 or by individual, or cap, molding techniques. Alternatively, a liquid encapsulant may be used.

Once the semiconductor chips 102 and 140 have been encapsulated, the cover material 180 is removed from over the through hole 110 to expose the active surface 142 of the semiconductor chip 140 and the co-planar lower surface of the encapsulant 162 around the active surface 142. With the active surface 142 exposed, the bond pads 146 of the active surface 142 may be electrically connected to the conductive circuit pattern 123 disposed on the second face 122 of the substrate 114. In this example, the wire ribbons 150 are connected between the input/output pads 146 of the active surface 142 and the bond fingers 152 of the second face 122.

The active surface 142, wire ribbons 150, and input/output pads 146 of the semiconductor chip 140 are then encapsulated, along with the bond fingers 152, with an insulative encapsulant 164. As shown in FIG. 1, the encapsulant 164 is individually molded or poured, rather than gang molded or gang poured, so as to not encapsulate the lands 126 disposed on the second face 122. Lastly, the conductive balls 170 may optionally be fused to the lands 126.

In an alternate embodiment, the semiconductor package 100 may be fabricated using a single encapsulation step wherein both the encapsulant 162 and the encapsulant 164 are molded to the chips 102 and 140 at the same time after semiconductor chips 102, 140 have each been electrically connected to bond fingers 124 and 152, respectively. Pursuant to this embodiment, care should be taken to maintain the chips 102 and 140 in their respective positions relative to the substrate 114 during the encapsulation. Cover material 180 may have apertures in the areas between chips 102, 140 and inner walls 112 f substrate 114, thereby allowing molten or liquid encapsulant material to flow through cover material 180 and encapsulate the chips 102, 140 and portions of first face 120 and second face 122 of substrate 114 in a unitary body of encapsulant in a single encapsulation step.

Subsequently, each package 100 formed on the substrate sheet is singulated from the other packages 100 formed therewith, such as by sawing or punching. The substrate sheet may be provided with preformed apertures adjacent the sides of each package site to ease singulation. Where encapsulant 162 is gang molded or gang poured, the singulation (e.g., sawing) may cut through both the substrate sheet and the encapsulant 162, thereby forming the orthogonal outer peripheral walls 116 of the package 100.

FIG. 2 illustrates a semiconductor package 200 having similar features as those discussed above and illustrated in FIG. 1. The details of these various similar features are discussed above and are not repeated in the discussion of FIG. 2.

As shown, the semiconductor package 200 also includes semiconductor chips 102 and 140. The stacked chips 102 and 140, respectively, may be of substantially equal horizontal area, just as in FIG. 1. The bond pads 108, 140 of the active surfaces 104 and 142 of the chips 102 and 140, respectively, are electrically coupled to the conductive circuit patterns 121 and 123 disposed on the first and second faces 120 and 122, respectively, in the same manner as described above with reference to FIG. 1.

The inactive surface 144 of the second semiconductor chip 140 is shown as being coplanar with the first face 120 of the substrate 114. The semiconductor chip 102 is mounted on the semiconductor chip 140 by securing the inactive surfaces 106 and 144 of the chips 102 and 140 by a die attach adhesive 160. In this configuration, the semiconductor chip 140 is completely disposed within the through hole 110 and the semiconductor chip 102 is disposed over and fully outside of the through hole 110.

In accordance with one embodiment, the semiconductor package 200 of FIG. 2 may be fabricated as follows. Initially, the substrate 114 is provided, typically, as part of a larger substrate sheet including rows and columns of interconnected substrates 114. Each substrate 114 is a site for the assembly of a package 200. At each site, a layer of a cover material 180 is temporarily applied to the first face 120 of the substrate 114, with the cover material 180 completely covering the opening of the through hole 110 at the first face 120. With the cover material 180 in place, the semiconductor chip 140 is disposed in the through hole 110 with the chip inactive surface 144 in adhesive contact with the cover material 180. In this configuration, the cover material 180 maintains the semiconductor chip 140 within the through hole 110 so that the inactive chip surface 144 is substantially coplanar with the first face 120 of the substrate 114.

With the semiconductor chip 140 positioned within the through hole 110, the bond pads 146 of the active surface 142 may be electrically connected to the conductive circuit patterns disposed on the second face 122 of the substrate 114. In particular, wire ribbons 150 are connected between the input/output pads 146 of the active surface 142 and the bond fingers 152 of the second face 122. Then, the semiconductor chip 140, the wire ribbons 150, the input/output pads 146, the bond fingers 152, and at least a portion of the second face 122 are encapsulated by an encapsulant 164. As shown, the encapsulant 164 covers the active surface 142 of the semiconductor chip 140, fills the through hole 110, and contacts the cover material 180 around the semiconductor chip 140. It should be noted that the encapsulant 164 is individually, or cap, molded, rather than gang molded, over the semiconductor chip 140 so that the lands 126 disposed on the second face 122 outward of the through hole 110 remain exposed.

After the encapsulant 164 has been applied, the cover material 180 is removed from the first face 120 to expose the inactive surface 144 of the semiconductor chip 140 and the surrounding encapsulant 164 and first face 120 of the substrate 114. With the cover material 180 removed, the semiconductor chip 102 is mounted on the semiconductor chip 140 by a die attach adhesive 160. The die attach adhesive 160 is disposed between the inactive surface 144 of the semiconductor chip 140 and the inactive surface 106 of the semiconductor chip 102, thus securing the chips 102 and 140 in rigid relation to each other, with inactive surface 106 of chip 102 above the plane of first face 120.

Next, the bond pads 108 of the active surface 104 of the semiconductor chip 102 are electrically connected to the respective ones of conductive circuit patterns 121 disposed on the first face 120 of the substrate 114. In particular, the wire ribbons 130 are connected between the input/output pads 108 of the semiconductor chip 102 and the bond fingers 124 of the first face 120.

The semiconductor chip 102 and the wire ribbons 130 are then encapsulated with encapsulant 162. The application of the encapsulant 162 may be by gang molding, as shown in FIG. 2, or by individual cap molding techniques that leave peripheral portions of the first face 120 unencapsulated. Lastly, the conductive balls 170 may be fused to the lands 126 of the second face 122.

In an alternate embodiment, the semiconductor package 200 may be fabricated using a single encapsulation step wherein both the encapsulant 162 and the encapsulant 162 are molded to the chips 102 and 140 at the same time. Pursuant to this embodiment, care should be taken to maintain the chips 102 and 140 in their respective positions relative to the substrate 114 during the encapsulation.

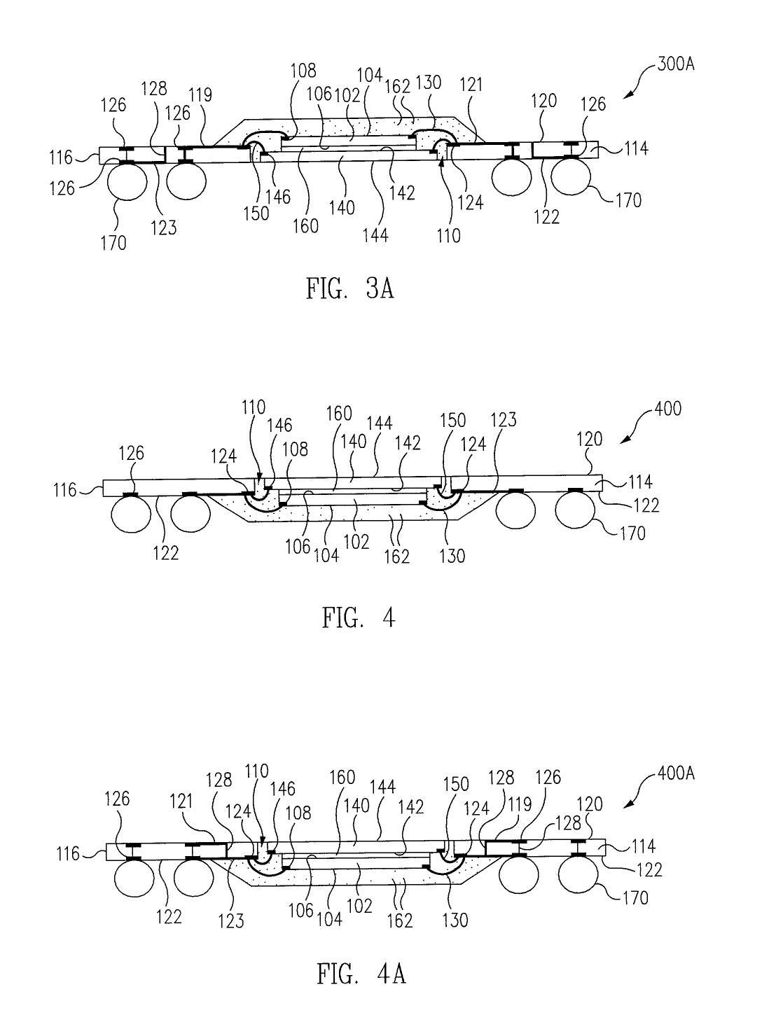

FIG. 3 illustrates a semiconductor package 300 in accordance with another embodiment of the present invention, wherein the two stacked semiconductor chips 102, 140 are different sizes. As shown, the semiconductor package 300 also includes semiconductor chips 102 and 140, but in this case the horizontal active and inactive surfaces 104 and 106, respectively, of the semiconductor chip 102 are smaller in area than the active surface 142 and the inactive surface 144 of the semiconductor chip 140. Such may be the case where semiconductor chips 102, 140 are different types of chips, such as a memory chip and a processor chip, among other possibilities. Alternatively, the semiconductor chip 102 may be a shrink version of the semiconductor chip 140, as is common with memory chips.

As in the package 100 of FIG. 1, the semiconductor chip 102 may be disposed fully within or partially within the through hole 110 with the semiconductor chip 140. Alternating chip 102 may be over and outside of the through hole 110, depending on the thickness of the substrate 114, the semiconductor chips 102 and 140, and the die attach adhesive 160.

The semiconductor package 300 may be fabricated in a manner similar to packages 100 with some modifications, as follows. The substrate 114 of the package 300 differs from the substrate 114 of the package 100 in that the bond fingers 152 and associated conductive patterns 123 are omitted from second face 122, since both semiconductor chips 102, 140 are electrically connected, as described below, to bond fingers 24 on the first face 120 of the substrate 114. Of course, other circuit patterns 123 coupled to vias 128 and including lands 126 remain on second face 122.

A cover material 180 is disposed on the second face 122 of the substrate 114 of FIG. 3 in such a manner that the cover material 180 completely covers the opening of the through hole 110 at the second face 122 of the substrate 114. With the cover material 180 in place, the semiconductor chip 140 is positioned within the through hole 110 with the inactive surface 114 of the semiconductor chip 140 in adhesive contact with the cover material 180. Next, the semiconductor chip 102 is mounted on the semiconductor chip 140 by disposing an electrically insulative die attach 160 between a portion of the active surface 142 of the semiconductor chip 140 and the inactive surface 106 of the semiconductor chip 102. The die attach 160 generally secures the chips 102 and 140 in rigid relation to each other. In this configuration, the inactive surface 106 of the semiconductor chip 102 does not cover the input/output pads 146 of the semiconductor chip 140, thus permitting the chips 102 and 140 to be stacked with their respective active surfaces 104 and 142 facing, or oriented in, the same direction, which in this example is in the same direction as the first face 120.

Next, the input/output pads 108, 146 of the active surfaces 104 and 142 of the chips 102 and 140, respectively are electrically connected to the conductive circuit patterns 121 disposed on the first face 120 of substrate 114. In particular, conductive means, such as the wire ribbons 130, electrically connect the input/output pads 108 of the semiconductor chip 102 with the bond fingers 124. Similarly, wire ribbons 150 electrically connect the input/output pads 146 of the semiconductor chip 140 with the bond fingers 124.

The wire ribbons 150 that are connected to the semiconductor chip 140 may be connected to an entirely different set or a same set of bond fingers 124 as the semiconductor chip 102. Thus, the semiconductor chips 102 and 140 may be electrically interconnected.

With the chips 102 and 140 electrically connected to the circuit patterns 121 of the first face 120 of the substrate 114, an encapsulation material 162 is molded or poured over the chips 102 and 140, the wire ribbons 130 and 150, the bond fingers 146, and all or a sub-portion of the first face 120 of the substrate 114 of FIG. 3. As shown, the encapsulation material 162 also fills the through hole 110 and secures the chips 102 and 140 to the substrate 114. Accordingly, the second face 122 of the substrate 114, the inactive surface 144 of the semiconductor chip 140, and a planar lower portion of the encapsulant material 162 are in a common horizontal plane. The encapsulation material 162 may be gang molded or gang poured, as shown in FIG. 3, or molded or poured individually so as to not cover the entire first face 120 of the substrate 114.

Next, the cover material 180 is removed to expose the inactive surface 144 of the semiconductor chip 140, thereby permitting dissipation of heat generated by the semiconductor chip 140 to ambient. In addition, with the cover material 180 removed, the lands 126 are exposed, either for use as input/output terminals of the package 300, or as sites for fusion of conductive balls 170 thereto. According to one embodiment, the package 300 may comprise a LGA-type package, without the conductive balls 170 attached thereto.

The embodiment of FIG. 3, may be modified to comprise a Land Grid Array (LGA) type package with the conductive balls 170 removed from the associated lands 126.

FIG. 3A illustrates a semiconductor package 300A in accordance with another embodiment of the present invention. The semiconductor package 300A is the same as the semiconductor package 300 of FIG. 3 and is made the same way, except as follows.

The semiconductor package 300A includes a substrate 114 that is identical to the substrate 114 of FIG. 3, except that the circuit pattern 121 on the first face 120 of the substrate 114 also includes lands 126. Further, encapsulant 162 is molded or poured cap-style so that the lands 126 on the first face 120 are exposed beyond the perimeter of encapsulant 162 for electrical connection to the balls 170 of a package 100 that is stacked on the package 300A. Of course, the package 300A could be modified to omit the semiconductor chip 120. In FIG. 3A, chip 102 can be fully in or only partially in through hole 110 with chip 140, or may be over and out of through hole 110, depending on component thicknesses, as discussed above.

FIG. 4 illustrates a semiconductor package 400 in accordance with another embodiment of the present invention. The semiconductor package 400 is similar to the semiconductor package 300, and has common features and generally is made the same way, except as follows.

First, the active surfaces 104, 142 of the semiconductor chips 102, 140 are oriented in a same direction as the second face 122 of the substrate 114 of FIG. 4. Second, the substrate 114 of FIG. 4 has conductive circuit patterns 123 on the second face 122 thereof, and may or may not have circuit patterns on the first face 120 thereof. Accordingly, the input/output pads 108, 146 of the semiconductor chips 102, 140 are electrically connected to bond fingers 150 of the second face 122 of the substrate 114 of FIG. 4.

Third, the encapsulation material 162 is shown as being individually molded or poured cap-style, so that the encapsulation material 162 does not cover entire second face 122 of the substrate 114 of FIG. 4, but is instead limited to covering the chips 102 and 140, the associated wire ribbons 130 and 140, and the bond fingers 124. The lands 126 are not covered by the encapsulant 162, which permits the conductive balls 170 to be connected to the lands 126.

The method of making the package 400 of FIG. 4 is essentially the same as for making the package 300 of FIG. 3, except that the substrate 114 of FIG. 4 is provided (rather than the substrate 114 of FIG. 3), and cover material 180 is applied to the first face 120 of the substrate 114 of FIG. 4. As in FIG. 3, one semiconductor chip (here semiconductor chip 140) is fully within the through hole 110, and the other semiconductor chip (here semiconductor chip 102) is either fully within, partially within, or out of and over the through hole 110, depending on various thicknesses, as discussed above.

FIG. 4A shows a stackable package 400A that is identical to the package 400 of FIG. 4, and is generally made the same way. A difference is that the package 400A includes a substrate 114 that is similar to the substrate 114 of FIG. 4, but also includes circuit patterns 121 on first face 120. Circuit patterns 121 include lands 126 and conductors 119 that electrically connect respective lands 126 to one or more vias 128. The vias 128 electrically connect the lands 126 to circuit patterns 123 on the second face 122 of the substrate 114. Accordingly, another package (e.g., package 100, 200, 300, 400, or 400A) may be stacked on package 400A in an electrical connection with the lands 126 formed on the first face 120, and may thereby be electrically connected to semiconductor chip 102, semiconductor chip 140, or both, of the package 400A.

In an alternative embodiment, packages 300, 300A, 400, and 400A may include chips 102, 140 that are the same size (e.g., FIG. 1), as would be the case where chips 102, 140 are identical memory chips. In such a case, die attach material 160 must be sufficiently thick to space the chip 102 or 140 whose inactive surface 106 or 144 is attached to the active surface 142 or 104 of the other chip 140 or 102 far enough away to clear wire ribbons 130 or 150, as the case may be. In such a case, the die attach material 160 may be an adhesive film entirely within a perimeter of the input/output terminals, may be a rigid insulated spacer have adhesive layers on its opposed surfaces, or may be a dab of an adhesive such as epoxy that flows over the wire ribbons. In this regard, the reader is directed to copending U.S. patent application Ser. Nos. 09/620,444 and 09/617,193, which are incorporated herein by reference in their respective entireties. The chips 102, 140 typically would be thinned or the substrate 114 relatively thick for the chips 102, 140 to both be fully within or partially within the through hole 110.

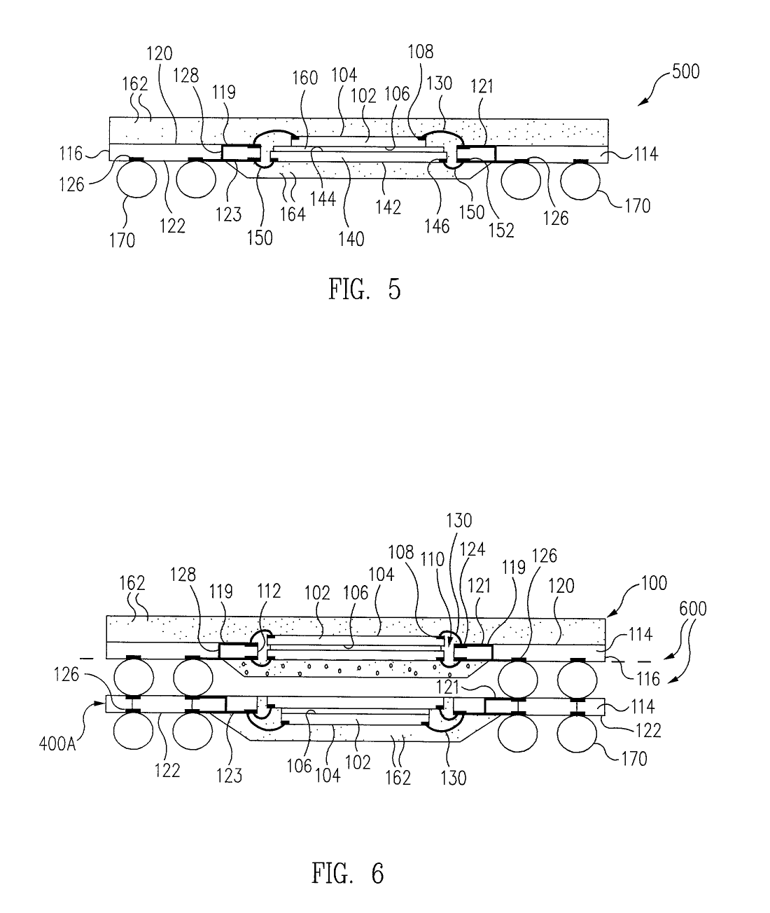

FIG. 5 illustrates a semiconductor package 500 in accordance with another embodiment of the present invention. The semiconductor package 500 is similar to the semiconductor package 100 of FIG. 1, and has common features and is made in the same way, except that chip 102 is smaller than chip 140. That is, the active and inactive surfaces 104, 106 of the semiconductor chip 102 are smaller in area than the active and inactive surfaces 142, 144 of the semiconductor chip 140, respectively. Despite the difference in the relative sizes of the chips 102 and 140, the package 500 may be fabricated using the fabrication methods described above with reference to FIG. 1.

FIG. 6 illustrates a stack 600 of electrically interconnected semiconductor packages in accordance with another embodiment of the present invention. As shown, the stack 600 includes the semiconductor package 100 of FIG. 1 stacked on a semiconductor package 400A of FIG. 4A. Alternatively, the package 100 of the stack 600 could be replaced by any of the packages 200, 300, 400, or 500, for example.

The semiconductor packages 100 and 400A are illustrated as being electrically connected, in stacked fashion, with the conductive balls 170 of package 100 electrically connected with the lands 126 disposed on the first face 120 of the substrate 114 of the package 400A. The semiconductor package 100 may be connected to the package 400A before or after the package 400A has been tested and mounted on a motherboard (not shown). For example, both packages 100, 400 may be memory devices, and the stacking of the packages could increase the memory capacity of a product including the stack 600.

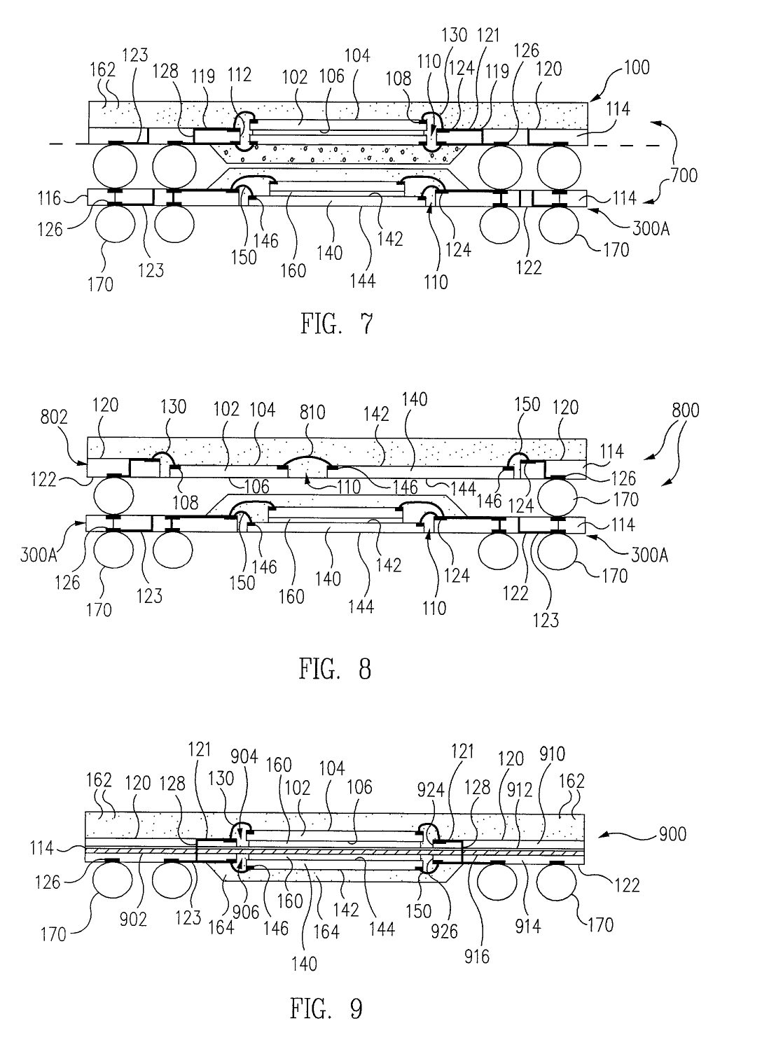

FIG. 7 illustrates a stack 700 of semiconductor packages in accordance with another embodiment of the present invention. As shown, the stack 700 includes semiconductor package 100 stacked on the semiconductor package 300A. Semiconductor package 100 may be replaced by any of the packages 200, 300, 300A, 400, 400A, or 500.

FIG. 8 illustrates a stack 800 of electrically connected semiconductor packages in accordance with another embodiment of the present invention. As shown, the stack 800 includes a semiconductor package 802 that is stacked on the package 300A (FIG. 3A).

The semiconductor package 802 includes a substrate 114 that is identical to the substrate 114 of the package 300 shown in FIG. 3, except that the through hole 110 is made significantly larger in area to accommodate two chips 102, 140 in a side by side arrangement. Some input/output pads 108 or 146 of the chips 102 and 140, respectively, are electrcially connected by wire ribbons 130 or 150 to bond fingers 124 on first face 120 of the substrate 114 of FIG. 8. Other input/output pads 108 of the semiconductor chip 102 are electrically connected to the input/output pads 146 of the semiconductor chip 140 by wire ribbons 810. The semiconductor chips 102 and 140 are disposed in side-by-side fashion within the through hole 110. Inactive surfaces 106 and 144 are coplanar with the second face 122.

The package 802 is made similar to the package 300, except that, instead of stacking chips 102, 140, the chips 102, 140 are arranged side by side with their inactive surfaces 106, 144 in adhesive contact with cover material 180 (see FIG. 3) prior to wire bonding and encapsulation.

As illustrated, the semiconductor package 802 is mounted on the semiconductor package 300A. Specifically, the balls 170 of the package 802 are electrically coupled to the lands 126 of the circuit patterns 121 on the first face 120 of the substrate 114 of the package 802 to mount the package 802 on top of, and in rigid relation to, the package 300A, as well as providing electrical connectivity between the packages 802 and 300A. The balls 870 of the package 802 are sized so as to provide sufficient spacing between the packages 802 and 300A so that the encapsulant 162 of package 300A does not interfere with the mounting or the operation of the package 802, or the like.

Moreover, due to the modular nature of the stack 800, the semiconductor package 802 may be connected to the package 300A before or after the package 300A has been tested and mounted on a motherboard (not shown).

FIG. 9 illustrates a semiconductor package 900 in accordance with another embodiment of the present invention. The package 900 includes semiconductor chips 102 and 140, which are mounted within opposed recesses 904, 906 and on opposed sides of a metal core 902 of a substrate 114. The metal core 902 is a layer of copper or some other metal, and provides for improved dissipation of heat generated by the chips 102, 140, EMI or RFI shielding, and/or electrical grounding of the inactive surfaces 106, 144 of the chips 102 and 140, respectively. The metal core 902 may also be useful in providing mechanical strength to the package 900 or a bias voltage to the inactive surfaces 106, 144 of the chips 102, 140.

In particular, the substrate 114 includes a first dielectric layer 910 formed on a first surface 912 of the metal core 902 and a second dielectric layer 914 formed on an opposite, second surface 916 of the metal core 902. The substrate 114 may be made by laminating a pre-formed sheet of an insulative material (such as polyimide or a polymetric resin) and an overlaying metal sheet to the respective first and second surfaces 912 and 916 of the metal core 902. The opposed circuit patterns 121 and 123 on the first and second faces 120 and 122 on the dielectric layers 910 and 914 may be formed by the metal sheets by photolithography. Alternatively, dielectric substrate material may be applied to the first and second surfaces 912 and 916 of the metal core 902 using a deposition method, followed by a step of forming circuit patterns 121, 123 on the deposited dielectric layers.

As illustrated, the first and second dielectric layers 910 and 914 have recesses 904 and 906 respectively formed therein. In particular, the recess 904 is adjacent a portion of the first surface 912 of the metal core 902 that is void of the first dielectric layer 910. Recess 904 is defined by an inner wall 924 and the first surface 912 of the metal core 902. Similarly, the recess 906 is adjacent a portion of the second surface 916 of the metal core 902 that is void of the second dielectric layer 914. Recess 906 is defined by an inner wall 926 and the second surface 914 of the metal core 902.

The inactive surface 106 of the semiconductor chip 102 is mounted on the first surface 912 of the metal core 902 using a die attach adhesive 160, which may be electrically conductive or insulative, and thermally conductive. Similarly, the inactive surface 144 of the semiconductor chip 140 is mounted on the second surface 912 of the metal core 902 using another die attach adhesive 160. The semiconductor chips 102 and 140 may be disposed entirely within, or only partially within, the corresponding recesses 904, 906 depending on the thicknesses of the first and second dielectric layers 910 and 914, the semiconductor chips 102 and 140, and the die attach adhesives 160.

The vias 128 extend through the first dielectric layer 910, the metal core 902, and the second dielectric layer 914 and electrically connect the conductive circuit patterns 121 on the first face 120 with the conductive circuit patterns 123 on the second face 122. To avoid short circuiting, any via not intended to connect to metal core 902 will pass through an aperture in metal core 902 and be separated from metal core 902 by an insulator.

The exemplary structures and methods herein provide, among other things, semiconductor packages and devices that are thin, despite having multiple chips disposed therein. This allows, among other things, a thin package having more capacity or functionality than semiconductor packages having only a single chip. In addition, the thin, multi-chip, packages are generally modular in nature and may be stacked with other packages, as desired, to provide additional capacity or functionality without an increase in footprint on the mounting surface. One embodiment also provides a package having improved mechanical strength, electrical grounding, power distribution, and heat dissipation characteristics by providing a thin, multi-chip, package having a metal core disposed therein.

While particular exemplary embodiments have been shown and described, it will be apparent to practitioners that various changes and modifications may be made without departing from our invention in its broader aspects. Accordingly, the appended claims encompass all such changes and modifications as fall within the scope of this invention.

1-25. (canceled)

26. A semiconductor package comprising:
a substrate having opposing first and second surfaces and a rectangular through hole extending through the substrate between the first and second surfaces, said rectangular through hole having four sides;
a first conductive circuit pattern disposed on the first surface of the substrate, and a second conductive pattern disposed on the second surface of the substrate, wherein the first conductive circuit pattern includes at least bond fingers and lands, the second conductive pattern includes at least lands, and at least some of the first and second circuit patterns are electrically coupled through the substrate;
a first semiconductor chip having opposed active and inactive surfaces, wherein the first semiconductor chip is disposed within the through hole without contacting the substrate, and the active surface of the first semiconductor chip includes bond pads;
a second semiconductor chip having opposed active and inactive surfaces, wherein the second semiconductor chip is disposed within or over the through hole without contacting the substrate, and the active surface of the second semiconductor chip includes bond pads,
wherein the inactive surface of the second semiconductor chip faces and is mounted on the active surface of the first semiconductor chip so that the active surfaces of the first and second semiconductor chips are oriented in a same direction;
a plurality of first conductive wires, wherein each of the first conductive wires electrically connects a respective one of the bond pads of the first semiconductor chip to a respective one of the bond fingers of the first conductive circuit pattern;
a plurality of second conductive wires, wherein each of the second conductive wires electrically connects a respective one of the bond pads of the second semiconductor chip to a respective one of the bond fingers of the first conductive circuit pattern, at least some of said first and second conductive wires being electrically connected to bond fingers located adjacent a first side of the rectangular through hole, and at least some of said first and second conductive wires being electrically connected to bond fingers located adjacent a second side of the rectangular through hole, the first and second sides of the through hole being opposite one another; and
an encapsulant filling the through hole and contacting the first surface of the substrate, the bond fingers of the first conductive circuit pattern, the first semiconductor chip, the second semiconductor chip, and the first and second conductive wires,
wherein the inactive surface of the first semiconductor chip is exposed through the encapsulant in a common plane with the second surface of the substrate, and the lands of the first and second conductive circuit patterns are uncovered by the encapsulant.

27. The semiconductor package of claim 26, wherein the inactive surface of the second semiconductor chip has a smaller area than the active surface of the first semiconductor chip.

28. The semiconductor package of claim 26, wherein the first and second semiconductor chips are a same size.

29. The semiconductor package of claim 26, further comprising a plurality of conductive balls, wherein each of the conductive balls is fused to a respective one of the lands of the second conductive circuit pattern, and the active surfaces of the first and second semiconductor dies are oriented in a same direction as the first surface of the substrate.

30. The semiconductor package of claim 29, wherein the inactive surface of the second semiconductor chip has a smaller area than the active surface of the first semiconductor chip.

31. The semiconductor package of claim 29, wherein the first and second semiconductor chips are a same size.

32. The semiconductor package of claim 26, further comprising a plurality of conductive balls, wherein each of the conductive balls is fused to a respective one of the lands of the first conductive circuit pattern, and the active surfaces of the first and second semiconductor dies are oriented in a same direction as the first surface of the substrate.

33. The semiconductor package of claim 32, wherein the inactive surface of the second semiconductor chip has a smaller area than the active surface of the first semiconductor chip.

34. The semiconductor package of claim 32, wherein the first and second semiconductor chips are a same size.
